(19) United States
(12) Patent Application Publication
(10) Pub. No.: US 2006/0021970 A1
(43) Pub. Date: Feb. 2, 2006

(54) Method and apparatus for non-invasive measurement and analysis of semiconductor process parameters

(75) Inventor: Richard Parsons, Mesa, AZ (US)

Correspondence Address: PILLSBURY WINTHROP SHAW PITTMAN, LLP, P.O. BOX 10500, MCLEAN, VA, 22102, US

(73) Assignee: Tokyo Electron Limited, Tokyo (JP)

(21) Appl. No.: 11/023,548

(22) Filed: Dec. 29, 2004

Related U.S. Application Data
(63) Continuation of application No. PCT/US03/19039, filed on Jun. 18, 2003.
(60) Provisional application No. 60/393,105, filed on Jul. 3, 2002.

(51) Int. Cl. G01L 21/30; H01L 21/306

(52) U.S. Cl. 216/59; 156/345.28; 156/345.24; 216/67

(57) ABSTRACT

A RF sensor for sensing and analyzing parameters of plasma processing. The RF sensor is provided with a plasma processing tool and an antenna for receiving RF energy radiated from the plasma processing tool. The antenna is located proximate to the plasma processing tool so as to be non-invasive. Additionally, the RF sensor may be configured for wideband reception of multiple harmonics of the RF energy that is radiated from the plasma processing tool. Further, the RF sensor may be coupled to a high pass filter and a processor for processing the received RF energy. Additionally, the antenna may be located within an enclosure with absorbers to reduce the interference experienced by the RF sensor. Additionally, a tool control may be coupled to the processor to provided to adjust and maintain various parameters of plasma processing according to the information provided by the received RF energy.

This is a Continuation of International Patent Application No. PCT/US03/19039, filed Jun. 18, 2003, which relies for priority on and claims the benefit of U.S. Provisional Application No. 60/393,105, filed Jul. 3, 2002, the contents of both of which are incorporated herein by reference in their entireties.

### BACKGROUND OF THE INVENTION

1. Field of the Invention

The present invention relates to plasma process tools, more particularly, the present invention relates to sensing equipment for non-invasive measurement and analysis of parameters of plasma process tools.

2. Description of Background Information

Plasma processing systems are of considerable use in material processing, and in the manufacture and processing of semiconductors, integrated circuits, displays, and other electronic devices, both for etching and layer deposition on substrates, such as, for example, semiconductor wafers. Generally, the basic components of the plasma processing system include a chamber in which a plasma is formed, a pumping region which is connected to a vacuum port for injecting and removing process gases, and a power source to form the plasma within the chamber. Additional components can include, a chuck for supporting a wafer, and a power source to accelerate the plasma ions so the ions will strike the wafer surface with a desired energy to etch or form a deposit on the wafer. The power source used to create the plasma may also be used to accelerate the ions or different power sources can be used for each task.

To insure an accurate wafer is produced, typically, the plasma processing system is monitored using a sensor to determine the condition of the plasma processing system. Generally, in such a system, the sensor is placed within the plasma to monitor certain parameters or in the transmission line coupled to an electrode within the processing chamber.

### SUMMARY OF THE INVENTION

The present invention provides a novel method and apparatus for measurement and analysis of plasma process parameters.

A RF sensor for sensing parameters of plasma processing is provided with a plasma processing tool and an antenna for receiving RF energy radiated from the plasma processing tool. The antenna is located proximate to the plasma processing tool so as to be non-invasive. The antenna may be a broadband mono-pole antenna.

In an aspect of the invention, a tool control may be coupled to a processor to control and maintain the plasma processing based on information provided by received RF energy from an antenna. The tool control can control the plasma processing tool, power sources, or other various components that may be present during plasma processing.

### BRIEF DESCRIPTION OF THE DRAWINGS

FIG. 1 is an illustration of a RF sensor in accordance with an embodiment of the present invention;

FIG. 2 is a simplified block diagram of an antenna and processor in accordance with an embodiment of the present invention;

FIG. 3 is a simplified block diagram of an antenna in accordance with an embodiment of the present invention;

FIG. 4 is a simplified block diagram of a plasma processing system in accordance with an embodiment of the present invention; and

FIG. 5 is a simplified graph of expected harmonic data in accordance with an embodiment of the present invention.

### DETAILED DESCRIPTION OF THE EMBODIMENTS

The present invention will be described in more detail below with reference to the illustrative embodiments disclosed.

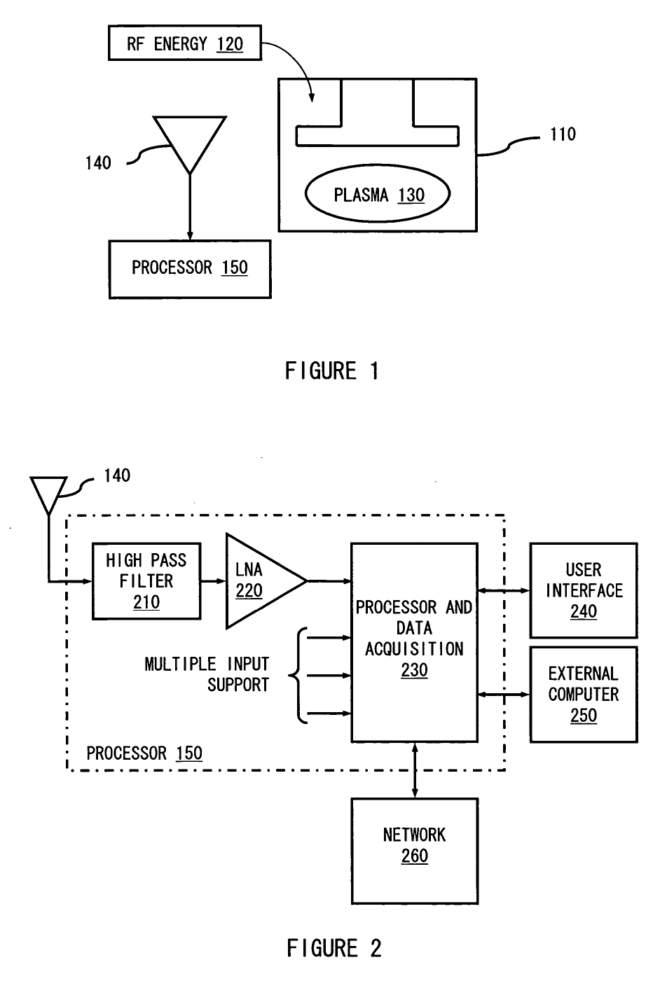

FIG. 1 is an illustration of a RF sensor in accordance with an embodiment of the present invention. A plasma processing tool includes a chamber 10. The plasma processing tool is generally powered by an RF power source (not shown). RF energy 120 from the RF power source creates and maintains a plasma 130 in the chamber 110 of the plasma processing tool that is generally used in the processing of substrates. The plasma processing tool can be assembled in any of a variety of known configurations, all of which contain a chamber 110 where a plasma 130 is present for processing. Some of these configurations include, for example, an inductively coupled plasma (ICP) source, an electrostatically shielded radio frequency (ESRF) plasma source, a transformer coupled plasma (TCP) source, and a capacitively coupled plasma (CCP) source. Regardless of the source of the RF energy, the plasma 130 inside of the chamber 110 is excited by the RF energy that is generated by the RF power source. Accordingly, RF energy radiates from the chamber 110 at the fundamental RF frequency and at harmonics of the fundamental RF frequency. The harmonic frequencies are generated in the plasma 130. The magnitude and the phase of the harmonic frequencies provide information on the state of the plasma 130 and the chamber 110. For example, experiments at various power, pressure, and flow rates indicate a high degree of correlation between the radiated energy and the process parameters. Specifically, analysis indicates that the first and second harmonics relate to the electron density of the plasma with better than a 99% match.

An antenna 140 is provided outside of the plasma chamber 110 to receive the RF energy that is radiated from the plasma 130 and converts the RF energy to an RF signal. In FIG. 1, antenna 140 is illustrated outside of chamber 110. Alternatively, it can be located within chamber 110, but outside of the processing area of plasma 130. In this configuration, the antenna has the benefit of being non-intrusive to the plasma 130 since invasive sensors are known to change the process parameters. The antenna 140 is coupled to a processor 150. The processor 150 receives the RF signal from the antenna 140 and accordingly, is configured to process the RF signal to provide the desired information on the state of the plasma. Additionally, since the fundamental frequency of the energy source may be in the order of megahertz, the antenna 140 may be a broadband, mono-pole antenna so it is capable of receiving the large bandwidth of the RF energy that is radiated. For example, an Antenna Research Model RAM-220 can be used as a broadband mono-pole antenna.

FIG. 2 is a simplified block diagram of an antenna and processor in accordance with an embodiment of the present invention. In the illustrated embodiment, the antenna 140 is coupled to a high pass filter 210. Alternatively, antenna 140 can be coupled to another type of filter such as a bandreject, a bandpass, or a lowpass filter. The output of the high pass filter 210 is coupled to a low noise amplifier (LNA) 220 and the amplified signal is then input to the processor 230. The high pass filter may be utilized to remove the fundamental frequency from the received signal since conventionally, there may not be useful information contained in the fundamental frequency but rather the useful information is contained within the harmonics of the RF energy. Of course, data concerning the fundamental frequency can be collected by eliminating or adjusting the cut-off frequency of the high pass filter 210. Typical attenuation of the signal below the cutoff of the high pass filter may be in the range of 40 dB. The LNA 220 amplifies the RF signal provided from the high pass filter so the signals can be appropriately processed by the processor 230. Typical gains of the LNA may be in the range of 20-30 dB.

The processor 230 may be configured to support multiple inputs as shown in FIG. 2. In this case, several processes may be monitored independently and processed by a single processor 230. The processor 230 may include an analog to digital (A/D) converter for converting the received analog signal into digital samples. The sampling rate of the signal may be determined in a variety of methods. If, for example, the fundamental frequency of the RF energy was 13.56 MHz, then a bandwidth of 125 MHz would be suitable to measure 8 harmonics (the 8^{th} harmonic having a frequency of 122.04 MHz). In this case, if the sampling interval the A/D converter is 100 ms and a frequency bin of 10 KHz is chosen, the sampling rate would be calculated as at least 250 MS/s by the Nyquist criterion and the sample size would be 25,000.

Coupled to the processor 230 are a user interface 240, an external computer 250, and a network 260. The user interface 240 can comprise a variety of known components with the purpose of allowing a user to interact with the processor 230. For example, if the processor, after sampling, were to perform a FFT (Fast Fourier Transform) of the sampled data, the results could be displayed on a touch screen that would allow the user to interface with the system. The external computer 250 can serve a variety of purposes including real time control of the processing parameters and the chamber 110. The network 260 serves to allow remote access to and from the processor by a user. For example, the FFT information can be made available to the external computer 250 or to the network 260.

In an example of such an antenna and processor, the chamber parameters can be characterized during a calibration state and the data collected by the antenna 140 can be applied to a model that relates various parameters of the chamber and plasma. For example, some of the parameters may include, electron density, assembly cleanliness, electron temperature, and endpoint detection. The use of such a model may permit the use of an antenna without regard to the absolute calibration of the antenna that may simplify sensor design parameters.

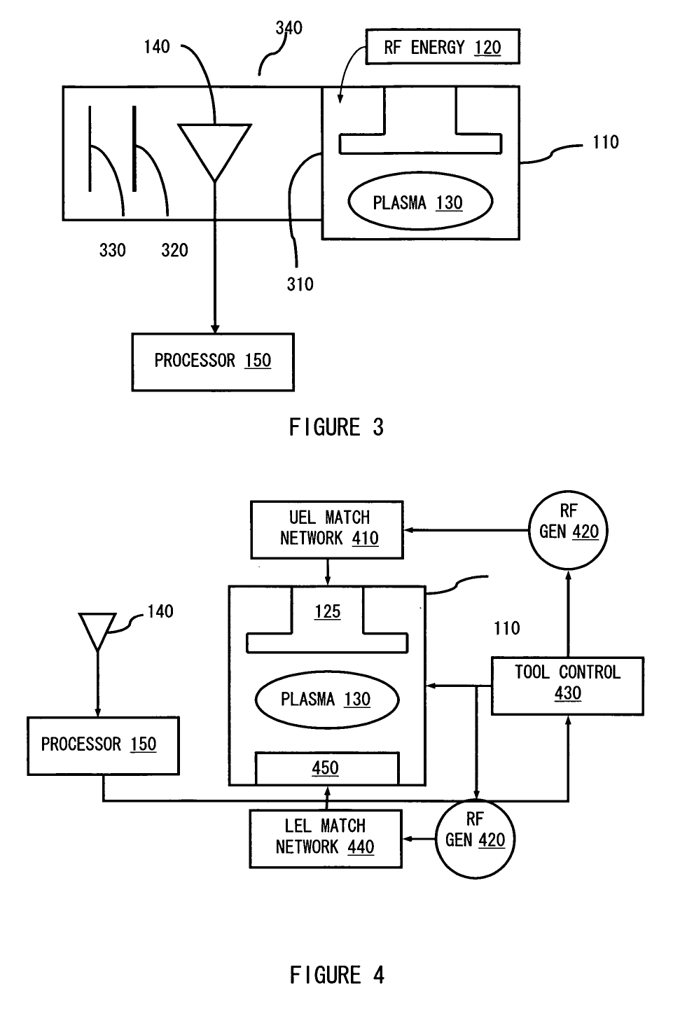

FIG. 3 is a simplified block diagram of an antenna in accordance with an embodiment of the present invention. The chamber 110, plasma 130, antenna 140, and processor 150 can be the same as those disclosed in FIGS. 1 and 2. The antenna 140 is placed in an enclosure 340 that is connected to the chamber 110 via the connecting wall 310. The connecting wall 310 is designed to pass the RF energy that is radiated from the plasma 130, and may be quartz, alumina or any other suitable material. Alternatively, a hole may be provided in the connecting wall 310 to allow the RF energy to pass therethrough. Absorbers 320 and 330 are utilized to absorb the RF energy from unwanted sources as well as to reduce the distortion caused by the resonance of the enclosure 340, i.e., without the absorbers 320 and 330, the antenna may receive unwanted resonance, distorting the signal that should be received. In general, the absorber can comprise material that absorbs energy at discrete or broadband frequencies.

Although shown on the back of the enclosure 340, the absorbers 320 and 330 may be placed around the enclosure 340 on five of the sides (if the enclosure is considered to be a rectangular box). This arrangement for the absorbers allows the RF energy to radiate from the plasma 130 through the connecting wall 310 and in the enclosure while the absorbers are on the other five sides of the box.

In embodiments, the absorbers 320 and 330 may be chosen such that absorber 320 is selected to absorb the fundamental frequency and absorber 330 is selected to absorb the first harmonic. A quarter wave arrangement can provide the maximum attenuation of the selected frequencies. Additionally, additional absorbing layers can be utilized as desired. Although specific arrangements of absorbers have been described above, any configuration of absorbers that reduce unwanted interference may be utilized.

FIG. 4 is a simplified block diagram of a plasma processing system in accordance with an embodiment of the present invention. For the purpose of description, the chamber 110 is shown as a capacitively coupled chamber with upper electrode 125, however, any type of system could be similarly utilized. The plasma 130, the antenna 140 and the processor 150 can be the same as described above. As previously described, the plasma 130 is excited by a RF generator 420. The RF generator 420 may be directly coupled to the chamber 110 or, as shown in FIG. 4, coupled to the chamber 110 via a match network 410 or 440. In FIG. 4, two RF generators are shown for the purpose of illustration, however, it may be possible to utilize a single RF Generator 420 depending on the configuration of the chamber 110. The Upper Electrode (UEL) match network 410 is coupled to the upper electrode 125 and the Lower Electrode (LEL) match network 440 is coupled to the lower electrode 450. The plasma 130 is excited by the RF generator(s) 420. Accordingly, the plasma 130 radiates RF energy at a fundamental frequency and at harmonics of the fundamental frequency. The RF energy is radiated out of the chamber 110 and is received by antenna 140, which is located exterior of the plasma 130. The antenna 140 is coupled to a processor 150, which has been described, in part, earlier. As described with respect to FIG. 1, the above-described arrangement provides a non-invasive method of receiving plasma processing parameters.

The processor 150 receives the RF energy and converts the analog signal to a digital signal via an analog to digital (A/D) converter. Typically, the sampling rate of the analog signal depends on the bandwidth of interest (i.e., the bandwidth is a function of the fundamental frequency and the harmonics of interest). For example, a 500 MHz bandwidth may typically be sampled at a rate of 1 billion samples per second. Of course, the sampling rate can be determined as desired and should not be limited to the example above. The magnitude and the phase of the RF energy, including the harmonics, may provide information about the state of the plasma 130 and accordingly on the state of the chamber 110. The data may then be processed by the processor 150 and operations such as a Fast Fourier Transform (FFT) and a Principle Component Analysis (PCA) can typically be used to gather information from the RF signal. The information that is acquired by the processor 150 can provide insight into parameters such as assembly cleanliness, plasma density, electron temperature, and endpoint detection.

In one embodiment of the processor, trace data of the received RF energy can be converted into a frequency domain output signal by using conventional techniques including the FFT. The information at the harmonic frequencies can then be extracted and multiplied by coefficients which are obtained during a calibration of the plasma processing system and determined by PCA. PCA may be useful for determining the coefficients because it allows a large set of correlated values to be converted to a smaller set of principal values. The reduction in the size of the set can be achieved be converting the original set of values into a new set of uncorrelated linear combinations of the original (larger) set.

Using the magnitude of the fundamental frequency and the harmonic frequencies of the received RF energy, it is possible to perform several different analyses including, power analysis, flow analysis, and pressure analysis. By processing the information obtained from the magnitude values, it is further possible to determine between which of the harmonics, the largest correlation exists and as a result, determine acceptable coefficients for each frequency component. Dependence analysis is also possible to determine if changes in one parameter effect other parameters in the system, however, initial results indicate that the parameters may be adjusted independently.

Further, endpoint detection may be possible from an analysis of the trace data. Once plotted, it becomes apparent that there is a significant shift in a harmonic of the received RF energy. More particularly, it is possible that the major harmonic contribution may change at the time of process completion.

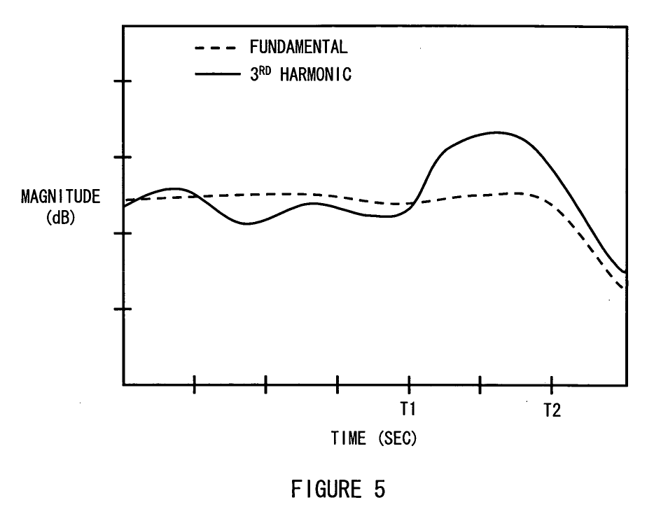

For example, as shown in FIG. 5 which illustrates simplified, expected data, a change in the 3^{rd} harmonic is apparent at T1 an a change in both the fundamental an 3^{rd} harmonic is apparent at T2. Analysis of the process indicates that these changes are due to completion of the process. Such a method of endpoint detection may be an accurate and cost effective method of endpoint detection.

The processed data is then sent to a tool control 430. The tool control 430 may be configured to perform several tasks. Some of the tasks that the tool control 430 can perform include end point determination, power control, and gas control (flow, pressure, etc.). As shown in FIG. 4, the tool control 430 is coupled to the chamber 110, and the RF generators 420. In this manner, it is possible for the tool control to adjust parameters of these devices according to the data that is received from processor 150 so that a repeatable process can be maintained within the chamber 110.

As described above, PCA is a multivariate statistical procedure that permits a large set of correlated variables to be reduced to a smaller set of principal components. Therefore, during a calibration phase, PCA can be utilized to first generate a covariance matrix from a data set comprising the data of various harmonics. Next, an eigensolution can be obtained from the covariance matrix and accordingly a set of eigenvectors can be calculated. From the eigensolution, the percentage contribution of each principal component can be calculated. Using the percentages, coefficients can be selected accordingly by a weighted sum of the eigenvector with the percentages obtained. This calculation can be performed for various parameters including, power, gas flow, and chamber pressure. Once the calibration is complete and the various coefficients are determined, the tool control can utilize the information in control loops as would be apparent to an individual skilled in the art. In this type of a feed back loop a reproducible process may be maintained.

The processor 150 may be coupled to several devices as shown in FIG. 2. Some of the devices that are of importance in the present embodiment include the user interface 240 and the external computer 250. Additionally, it is possible that both the user interface 240 and the external computer 250 are a single device, for example, a personal computer.

Lastly, as can be appreciated by an individual skilled in the art, the amount of data that is processed by the processor 150 may be significantly large. To this regard, it may be required that an external storage device (not shown) be utilized. One possible configuration for connecting the storage device may be directly to the processor 150. Alternatively, it may be beneficial to use the remote storage via the network 260 (shown in FIG. 2). However, any method of storing the data is acceptable. One benefit of storing the data is for future processing and analysis. Additionally, the archived data can be utilized to model an acceptable control system for operating the tool control 430 and, accordingly, control the plasma processing.

The foregoing presentation of the described embodiments is provided to enable any person skilled in the art to utilize the present invention. Various modifications to these embodiments are possible and the generic principle of a RF sensor for measurement of semiconductor process parameters presented herein may be applied to other embodiments as well. Thus, the present invention is not intended to be limited to the embodiments shown above, but rather to be accorded the widest scope consistent with the principles and novelty of the features disclosed in any fashion herein.

What is claimed is:

1. A method for controlling plasma processing comprising:
providing an antenna proximate to a plasma processing tool;
sensing RF energy radiated from said plasma processing tool;
processing said received RF energy; and
adjusting plasma processing parameters according to said processed RF energy;
wherein said RF energy radiated from said plasma processing tool consists of a fundamental frequency and at least one harmonic frequency; and
wherein said adjusting of plasma processing parameters is performed according to information obtained from signal characteristics obtained during processing of said fundamental frequency and said at least one harmonic frequency.

2. The method of claim 1, wherein said processing includes at least one of power analysis, flow analysis, and pressure analysis.

3. The method of claim 1, wherein said processing includes converting said RF energy to a digital signal.

4. The method of claim 3, wherein said digital signal is stored in an electronic storage device.

5. The method of claim 1, wherein said adjusting of plasma processing parameters is performed by a tool control, said tool control coupled to an energy source for plasma processing and a chamber for plasma processing.

6. The method of claim 5, wherein said adjusting of plasma processing parameters includes at least one of power control, flow control, and pressure control.

7. A controller for plasma processing comprising:
an antenna located proximate to a plasma processing tool for receiving RF energy from said plasma processing tool;
a processor coupled to said antenna for processing said RF energy received from said antenna; and
a tool controller for controlling said plasma processing tool according to said processed RF energy;
wherein said RF energy radiated from said plasma processing tool consists of a fundamental frequency and at least one harmonic frequency;
wherein said tool controller controls plasma processing parameters according to information obtained from signal characteristics obtained from said processor of said fundamental frequency and said at least one harmonic frequency.

8. The controller of claim 7, wherein said processor performs at least one of power analysis, flow analysis, and pressure analysis.

9. The controller of claim 7, wherein said processor converts said RF energy to a digital signal.

10. The controller of claim 9, wherein said digital signal is stored in an electronic storage device.

11. The controller of claim 7, wherein said tool controller is coupled to an energy source for plasma processing and a chamber for plasma processing.

12. The controller of claim 11, wherein said tool controller controls at least one of power control, flow control, and pressure control.
